(19) United States
(12) Patent Application Publication
(10) Pub. No.: US 2023/0087151 A1
(43) Pub. Date: Mar. 23, 2023

(54) FIELD PLATE ARRANGEMENT FOR TRENCH GATE FET

(71) Applicant: TEXAS INSTRUMENTS INCORPORATED, Dallas, TX (US)

(72) Inventors: Thomas Grebs, BETHLEHEM, PA (US); Meng-Chia Lee, ALLEN, TX (US); Hong Yang, WYLIE, TX (US); Ya ping Chen, Chengdu (CN); Sunglyong Kim, ALLEN, TX (US)

(21) Appl. No.: 17/502,692

(22) Filed: Oct. 15, 2021

(30) Foreign Application Priority Data
Sep. 17, 2021 (CN) 202111091799.6

(51) Int. Cl. H01L 29/40; H01L 29/78; H01L 29/66

(52) U.S. Cl. CPC H01L 29/407; H01L 29/7813; H01L 29/401; H01L 29/66734

(57) ABSTRACT

A trench gate metal oxide semiconductor (MOSFET) device includes a substrate with a semiconductor surface layer doped a first conductivity type. At least one trench gate MOSFET cell is located in or over the semiconductor surface layer, and includes a body region in the semiconductor surface layer doped a second conductivity type, and a source region on top of the body region doped the first conductivity type. A trench extends down from a top side of the semiconductor surface layer, the trench abutting the body region and being lined with a dielectric material. A field plate that includes polysilicon is located in the trench, and a gate electrode is located over the field plate. The field plate has a bottom portion, a middle portion, and a top portion, wherein the bottom portion is narrower than the middle portion, and the middle portion is narrower than the top portion.

### FIELD

This Disclosure relates to semiconductor devices, more particularly to vertical trench gate metal oxide semiconductor field effect transistors (MOSFETs).

### BACKGROUND

One type of power MOSFET is a trench gate MOSFET which is designed to handle significant power and to provide a high-power drive capability by vertically conducting current from a top surface to a bottom surface of the semiconductor die. The trench gate MOSFET in its active region generally includes a large number of parallel connected active trench gate MOSFET cells each including a trench formed in the semiconductor die, with each active trench having surrounding source regions and oppositely-doped body regions, and where the trenches are deep enough to cross through the body regions to a drift region below the top surface of the semiconductor die.

Each active trench gate cell has a gate stack buried in the trench comprising a gate electrode generally including doped polysilicon and a gate dielectric. The gate electrodes when appropriately biased controls the current conduction in the body region in their vicinity by virtue of the field effect that enables the MOSFET cells to be turned on, thus enabling current to flow between the source and the drain that has a drain contact on a bottom side of the semiconductor die.

### SUMMARY

This Summary is provided to introduce a brief selection of disclosed concepts in a simplified form that are further described below in the Detailed Description including the drawings provided. Various disclosed methods and devices of the present disclosure may be beneficially applied to transistors and integrated circuits that include trench field plates. While such embodiments may be expected to reduce defects, e.g. leakage between trench gates a surrounding source region, no particular result is a requirement unless explicitly recited in a particular claim.

Future generation trench gate MOSFETS may require a 2× thicker field plate dielectric layer along the trench (trench wall dielectric) to accommodate a 100 V operating voltage as compared to 45 V technology, the thicker field plate dielectric providing a higher dielectric breakdown voltage. However, the inventors have discovered that a thicker trench wall dielectric layer may result in significant recess in the top portion of the sidewall of the trench wall dielectric layer during a wet etch process that takes place before a bottom dielectric (e.g., silicon oxide) layer is grown to isolate the gate electrode from the field plate. This undercut can result in defects in the gate dielectric in which the gate dielectric is significantly thinner in the recess than at the rest of the gate electrode, degrading the electrical isolation between the gate electrode and the field plate. Such defects can cause significant current leakage between the gate and the source, resulting in yield loss.

The inventors have discovered that such defects may be reduced or eliminated by thinning down a small portion of the top trench wall dielectric layer at the top of the trench field plate. Where a baseline device may have a field plate with two widths (a double-width field plate), the addition of the thin trench wall dielectric layer portion results in a field plate with three different widths (a triple-width field plate) a corresponding trench wall dielectric layer with three different thicknesses along the field plate in the height/thickness direction of the trench. Although examples are described herein having three different polysilicon widths for the field plate, it is possible to also have four or more polysilicon widths for the field plate.

Disclosed aspects include a trench gate MOSFET device that has a substrate with a semiconductor surface layer doped a first conductivity type. At least one trench gate MOSFET cell is located in or over the semiconductor surface layer, and includes a body region in the semiconductor surface layer doped a second conductivity type, and a source region on top of the body region doped the first conductivity type. A trench extends down from a top side of the semiconductor surface layer, the trench abutting the body region and being lined with a dielectric material. A field plate that includes polysilicon is located in the trench, and a gate electrode is located over the field plate. The field plate has a bottom portion, a middle portion, and a top portion, wherein the bottom portion is narrower than the middle portion, and the middle portion is narrower than the top portion.

Disclosed aspects further include a method of fabricating a transistor. The method includes forming a plurality of trenches in a semiconductor layer over a semiconductor substrate, the plurality of trenches including a first trench and a second trench. A gate dielectric layer is formed on first and second sidewalls of the trench, and a gate electrode between the first and second sidewalls. A dielectric liner is formed on the first and second sidewalls, the dielectric liner having a first portion at a bottom of the trench with a first thickness, a second portion between the first portion and the gate dielectric layer with a second thickness less than the first thickness, and a third portion between the second portion and the gate dielectric layer with a third thickness less than the second thickness. A conductive field plate is formed in the trench, the field plate having a bottom portion with a first width, a middle portion between the bottom portion and the gate electrode with a second width greater than the first width, and a top portion between the middle portion and the gate electrode with a third width greater than the second width.

### BRIEF DESCRIPTION OF THE DRAWINGS

Reference will now be made to the accompanying drawings, which are not necessarily drawn to scale, wherein:

FIG. 1 depicts a high-level top view depiction of a disclosed vertical trench gate MOSFET device having a plurality of active trench gate MOSFET cells in an active region of the die along with an outer junction termination trench that provides a junction termination region which surrounds the active region of the device, where the polysilicon gates are shown by example being parallel to one another.

FIG. 2 is a cross sectional view along the cutline A-A′ shown in FIG. 1 that shows an example trench gate n-channel MOSFET device having a triple width field plate.

FIGS. 3A-3I show successive cross-sectional views for an in-process disclosed trench gate n-channel MOSFET device having active trench gate cells with a triple width field plate, corresponding to steps in a first example method of forming the trench gate n-channel MOSFET device shown in FIG. 2.

FIGS. 4A-4I show successive cross-sectional views for an in-process disclosed trench gate n-channel MOSFET device having active trench gate cells with a triple width field plate, corresponding to steps in a second example method of forming the trench gate n-channel MOSFET device shown in FIG. 2.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Also, the terms “connected to” or “connected with” (and the like) as used herein without further qualification are intended to describe either an indirect or direct electrical connection. Thus, if a first device “connects” to a second device, that connection can be through a direct electrical connection where there are only parasitics in the pathway, or through an indirect electrical connection via intervening items including other devices and connections. For indirect connecting, the intervening item generally does not modify the information of a signal

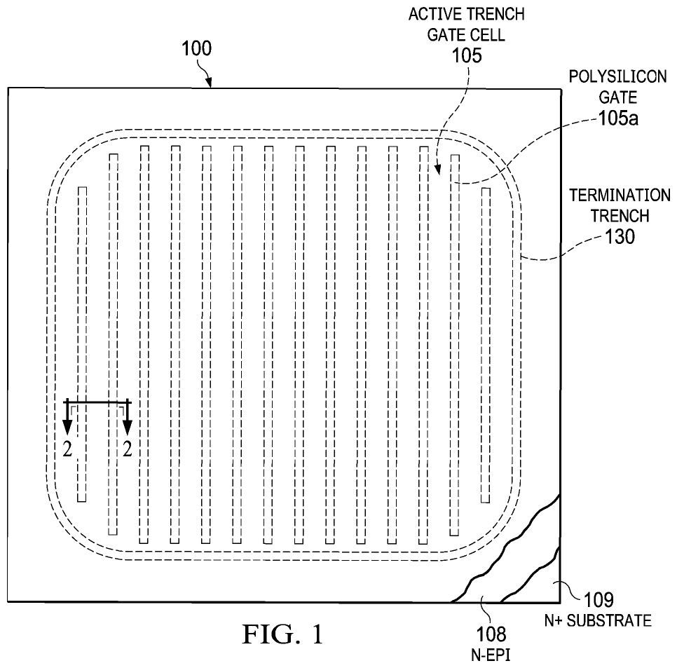

FIG. 1 depicts an enhanced high-level top view depiction of a disclosed vertical trench gate n-channel MOSFET device 100 shown with an optional outer gate junction termination trench 130 which provides a junction termination region that surrounds the active region having the plurality of active trench gate MOSFET cells 105 shown each having a polysilicon gate 105a. Although NMOS transistors are generally described herein, it should be clear to one having ordinary skill in the art to use this information disclosed in this application to also form PMOS transistors, by n-doped regions being substituted by p-doped regions, and vice versa.

The active region has a plurality of active trench gate MOSFET cells 105 with their polysilicon gates 105a shown, with their length direction being oriented parallel to one another. The trench gate MOSFET device 100 is shown formed on a substrate 109, e.g. n+ doped (about 10¹⁹ cm⁻³ to about 10²¹ cm⁻³), that provides a drain for the device 100. The substrate 109 has having an epitaxial surface layer 108 thereon of the same conductivity type and lightly doped (about 10¹⁴ cm⁻³ to about 10¹⁸ cm⁻³). Although not shown, there is generally a metal drain contact layer (e.g., Ti/Ni/Ag) on the bottom side of the substrate 109.

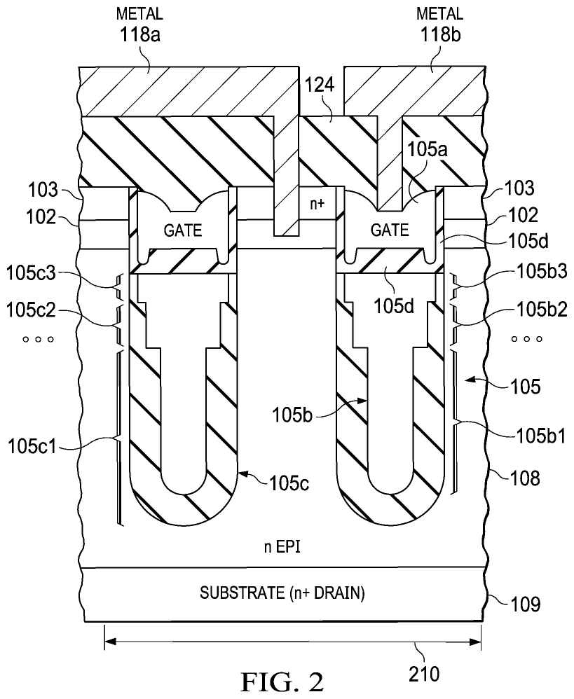

The junction termination trench 130 provides the junction termination region that surrounds the active region for the MOSFET device 100 that enables the MOSFET device 100 to sustain a higher drain to source breakdown voltage (BV). The junction termination trench 130 is generally connected to a field plate 105b (FIG. 2), e.g., comprising polysilicon, in the active trench gate MOSFET cells and the source.

The active area as described below in FIG. 2 (shown as 210) has body regions 102 and first doped regions 103, also referred to as source(s) 103, within the body regions 102 to provide a MOSFET device structure that enables turning on the active trench gate MOSFET cells 105 with a proper gate-to-body region bias to form a conduction channel which enables current to flow between the source regions 103 through the surface layer 108 as a drift region to the substrate 109 (e.g., functioning as a drain). In one example, the body regions 102 may be p-type with a dopant concentration in a range from about 10¹⁷ cm⁻³ to about 10¹⁹ cm⁻³, and the source regions 103 may be n-type with a dopant concentration in a range from about 10¹⁹ cm⁻³ to about 10²¹ cm⁻³.

FIG. 2 is a cross sectional view taken along the cut line 2-2 shown in FIG. 1 that shows an example trench gate n-channel MOSFET device's (trench gate MOSFET device) 200 in the active area 210, with a plurality of active trench gate MOSFET cells 105 (shown as two cells for a simplified example) each having a triple width field plate 105b. The trench gate MOSFET device 200 can comprise a discrete device that only includes the plurality of active trench gate MOSFET cells 105. Alternatively, the trench gate MOSFET device can comprise an integrated circuit (IC). For example, the IC can include a gate driver with a plurality of trench gate MOSFET cells 105 hooked up in parallel being all driven by the gate driver.

The field plate 105b comprises a bottom portion 105b1, a middle portion 105b2, and a top portion 105b3, all in the active area 210 of the trench gate MOSFET device 200. A trench wall dielectric layer 105c, e.g. silicon oxide, comprises a bottom portion 105c1, a middle portion 105c2, and a top portion 105c3. The triple width arrangement of the field plate 105b is distinct from a double width field plate structure without a breakdown voltage degradation. The top portion 105c3 of the trench dielectric wall dielectric 105b, because it occupies a comparatively small portion of the trench wall dielectric's total height, has a generally minimal impact on the BV between the gate electrode 105a and the source region 103, which is typically conductively connected on the semiconductor die to the field plate.

In some examples, the height (in a direction normal to the top surface of the surface layer 108) of the bottom portion 105b1 may be in a range from 3 μm to 4 μm, the height of the middle portion 105b2 may be in a range from 0.7 μm to 1.5 μm, the height of the top portion 105c3 may be in a range from 1,000 Å to 5,000 Å, and the total height of the field plate 105b may be in a range from 3.8 μm to 5.6 μm. In some examples, the thickness (parallel to the top surface of the surface layer 108) of the bottom portion 105b1 may be in a range from 1,000 Å to 3,000 Å, the thickness of the middle portion 105b2 may be in a range from 5,000 Å to 11,000 Å, and the thickness of the top portion 105b3 may be in a range from 7,000 Å to 13,000 Å. In some examples, the thickness (parallel to the top surface of the surface layer 108) of the bottom portion 105c1 of the trench wall dielectric layer 105c may be in a range from 3,000 Å to 8,000 Å, the thickness of the middle portion 105c2 may be in a range from 1,500 Å to 2,500 Å, and the thickness of the top portion 105c3 may be in a range from 700 Å to 1,300 Å.

In a more specific example, presented without implied limitation, the height of the bottom portion 105b1 may be about 3.4 μm, the height of the middle portion 105b2 may be about 1.1 μm, and the height of the top portion may be about 3,000 Å; the thickness of the bottom portion 105b1 may be about 2,000 Å, the thickness of the middle portion 105b2 may be about 8,000 Å, and the thickness of the top portion 105b3 may be about 1 μm; and the thickness of the bottom portion 105c1 may be about 5,000 Å, the thickness of the middle portion 105c2 may be about 2,000 Å, and the thickness of the top portion 105c3 may be about 1,000 Å

In the case that the field plates 105b are formed from doped polysilicon, the polysilicon can be doped (e.g., n+ or p+), which can comprise in-situ doping during the polysilicon deposition, or ion implantation of undoped polysilicon with one or more dopant ions. Alternatively, because the field plate 105b does not conduct any electrical current during trench gate MOSFET device operation, the field plate can also comprise undoped polysilicon.

The source regions 103 are shown as n+ doped for acting as a source for the active trench gate MOSFET cells 105 formed with the body regions 102. The active trench MOSFET cells 105 generally have a polysilicon gate 105a with a gate dielectric layer 105d below the polysilicon gate 105a and between the sidewalls of the polysilicon gate 105a and the body region 102 and the source region 103. The total gate dielectric layer 105d thickness may be in a range from 100 Å to 10,000 Å. The triple shield field plate 105b portions 105b1, 105b2 and 105b3 are shown below the gate dielectric layer 105d under the polysilicon gate 105a. The gate 105a, the source region 103, and the substrate 109 operates as a 3-terminal trench gate MOSFET cell 105, with the source region 103 being tied to the body region 102.

The polysilicon gates 105a are optionally shown having gate recesses (indentations) that have a pre-metal dielectric (PMD) layer 124 above that also fills the gate recesses. Recessed gates may provide more process margin for the source contacts.

The trench dielectric layer 105c comprising portions 105c1, 105c2, and 105c3 can comprise thermal silicon oxide with a deposited dielectric layer thereon, that may also comprise silicon oxide, or another dielectric material such as silicon nitride or silicon oxynitride, or a material comprising a high-k dielectric (e.g., k>5) such as HfO₂. A metal 1 (M1) layer is over and fills contact apertures formed in the PMD layer 124 shown with a metal contact 118a connecting the source region 103 and body region 102 of the active trench gate MOSFET cells 105, and a metal contact 118b providing a common connection to the polysilicon gates 105a of the active trench gate MOSFET cells 105.

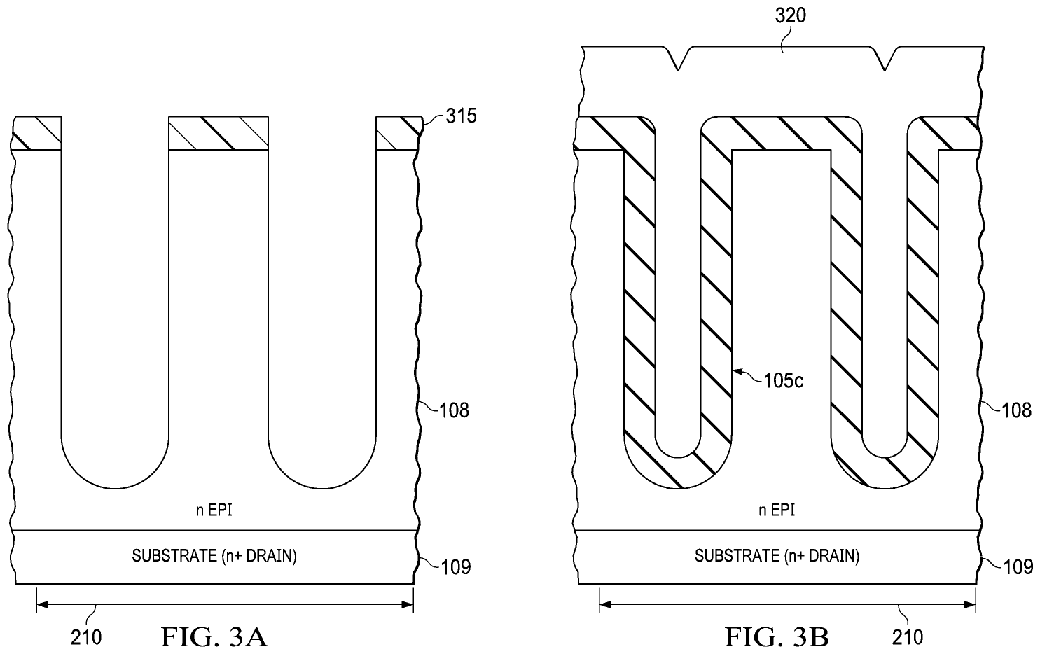

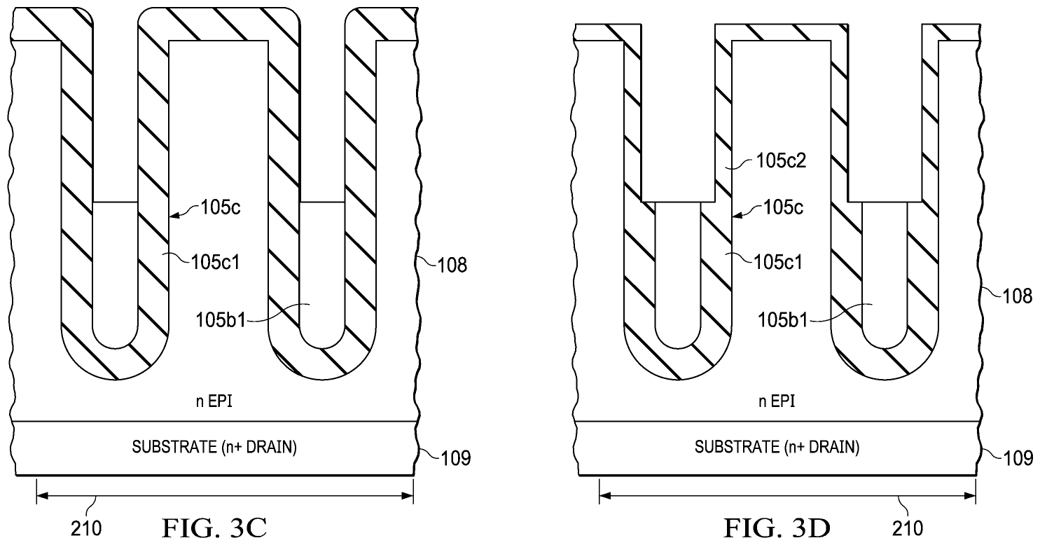

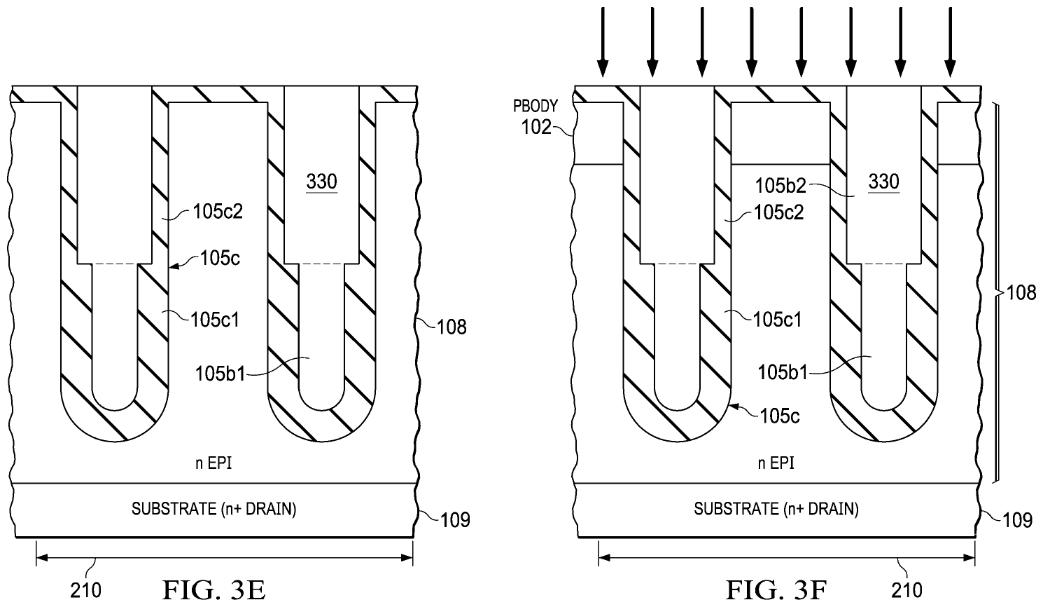

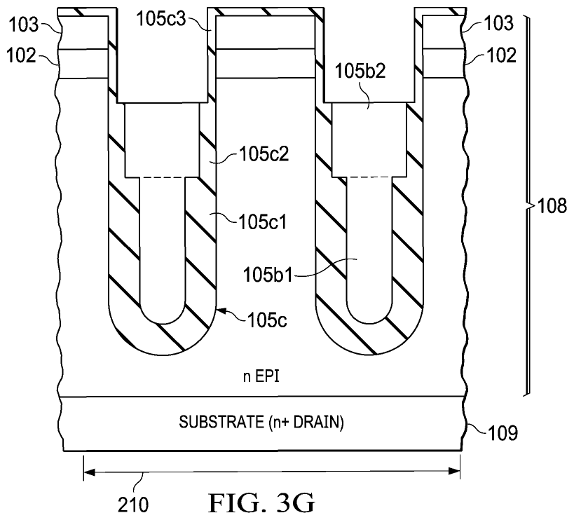

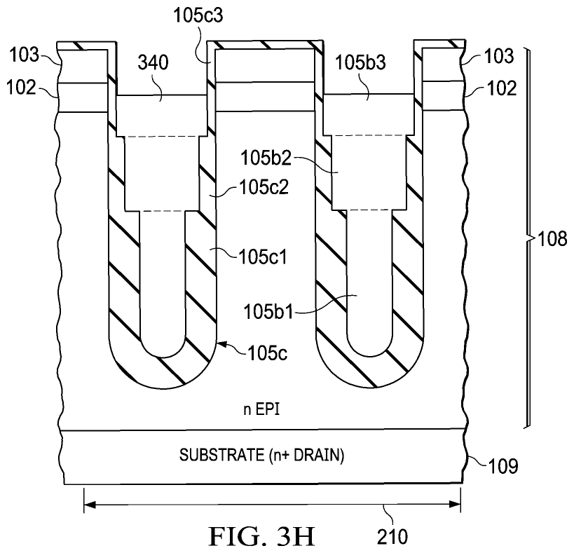

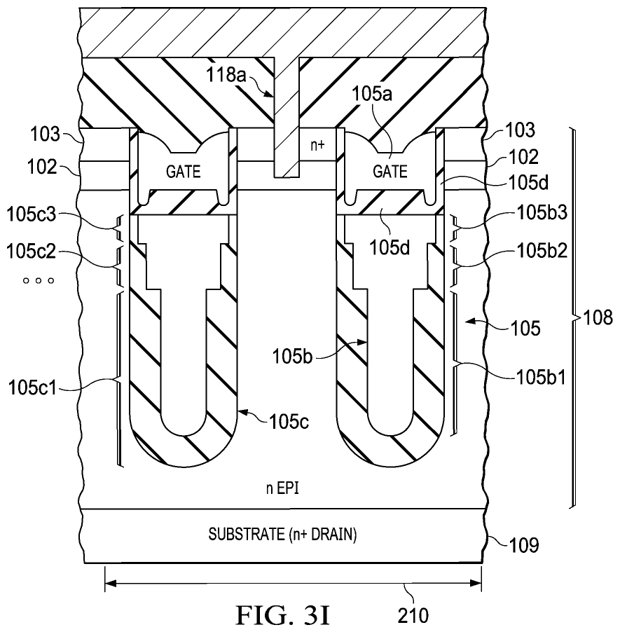

A process flow is now described performing a disclosed trench gate MOSFET device including a triple field plate. FIGS. 3A-3I show successive cross-sectional views of an example in-process disclosed vertical trench gate n-channel MOSFET device with a triple width field plate for the active trench gate MOSFET device 200 shown in FIG. 2 comprising the trench gate MOSFET cells in the active area 210 of the MOSFET device. The process flow shown in FIGS. 3A-3I creates a triple width field plate structure from bottom side to the top side by successively filling the trench with polysilicon followed by chemical mechanical polishing (CMP) and etching back.

FIG. 3A shows a cross sectional view of the in-process trench gate MOSFET device after silicon trench etching in the surface layer 108 on a substrate 109 providing a drain, generally by Reactive Ion Etching (RIE) to form the trench apertures shown in the surface layer 108. A patterned hard mask (HM) layer, shown as HM layer 315, such as comprising silicon nitride, is generally used in this step. Although not shown, there is generally a thin silicon pad oxide layer under the HM layer 315. The trench depth is generally 1 μm to 10 μm.

FIG. 3B shows a cross sectional view of the in-process trench gate MOSFET device after forming a trench dielectric layer shown as 105c1, followed by a polysilicon deposition for forming a polysilicon layer 320 as an initial filler material of the active trench MOSFET gate cells in the active area 210. The trench dielectric layer 105c1 is generally formed by growing a thermal oxide liner 500 Å to 2,000 Å thick followed by a sub-atmospheric chemical vapor deposition (SACVD) of silicon oxide generally 1,000 Å to 5,000 Å thick.

FIG. 3C shows a cross sectional view of the in-process trench gate MOSFET cell after polysilicon CMP to remove polysilicon layer overburden outside the trenches, then a polysilicon etch-back process that exposes the trench gate MOSFET cells in the active area 210, with the resulting polysilicon layer in the active area trenches now shown as 105b1. FIG. 3D shows a cross sectional view of the in-process trench gate MOSFET device after oxide pull back of the trench dielectric layer 105c1 in the active area 210 to form a thinned trench dielectric layer now shown as 105c2. The oxide pull-back process generally comprises a wet etch.

FIG. 3E shows a cross sectional view of the in-process trench gate MOSFET device after forming a polysilicon layer 330 as a second filler material of the active trench MOSFET gate cells. In the illustrated view, a CMP process has been performed to remove the polysilicon layer 330 over the top surface of the dielectric layer 105c. FIG. 3F shows a cross sectional view of the in-process trench gate MOSFET device after a body implant (shown by arrows) that forms the body regions 102 at the surface of the surface layer 108.

FIG. 3G shows the cross-sectional view of the in-process trench gate MOSFET device after ion implanting to form a source region 103 (e.g., a source) in the body regions 102, then etching a portion of the second polysilicon layer 330 to provide the middle field plate polysilicon portion now shown as 105b2. FIG. 3H shows the cross-sectional view of the in-process trench gate MOSFET device after depositing a third polysilicon layer 340 as a third filler material of the active trench MOSFET gate cells. In the illustrated view, a CMP process has been performed to remove the polysilicon overburden over the top surface of the dielectric layer 105c, and an etch process has been performed to recess the third polysilicon layer 340 below the top surface of the surface layer 108. These operations result in the top field plate portion 105b3 that can be seen to be the widest of the field plate portions. Top field plate portion 105b3 completes the triple field plate for the trench gate MOSFET cells.

FIG. 31 shows the cross-sectional view of the in-process trench gate MOSFET device after a thermal gate oxidation to form the gate dielectric layer 105d, where as shown in FIG. 31 the gate dielectric layer 105d will as shown generally grow thicker over the exposed top of the top field plate portion 105b3 as compared to the vertical channel region over the silicon mesa comprising the surface layer 108 between the trenches. The gate dielectric layer 105d over the silicon be in a range from about 100 Å (e.g., for 5 V operation) to about 1,000 A thick (for higher voltage device operation, e.g. 100 V).

Gate polysilicon deposition and patterning follows to form the polysilicon gates 105a shown with optional polysilicon gate recesses, followed by the deposition of the PMD layer 124 which also fills the gate recesses, followed by contact aperture formation through the PMD layer 124 to expose the source region 103 and body region 102 shown recessed into the silicon, and to expose the polysilicon gates 105a. As described above the polysilicon gates are doped. Metal 1 formation follows to provide metal contacts including metal contacts 118a to source region 103 and body region 102, and another metal contact that is not shown in FIG. 31 (see metal 118b in FIG. 2 described above) which contacts the polysilicon gates 105a. The metal for the metal contacts can comprise aluminum, or other metal materials such as tungsten or cobalt.

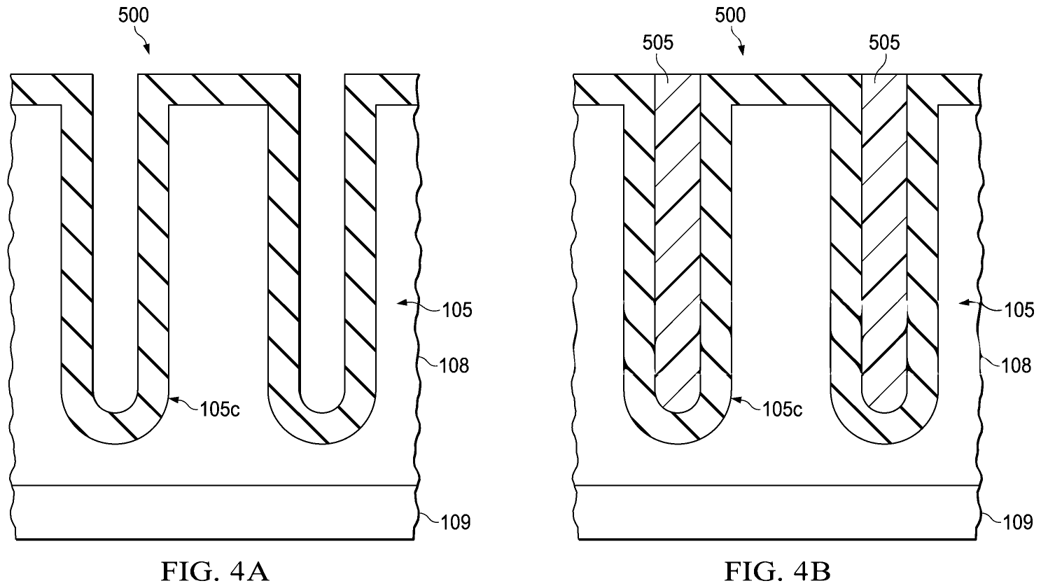

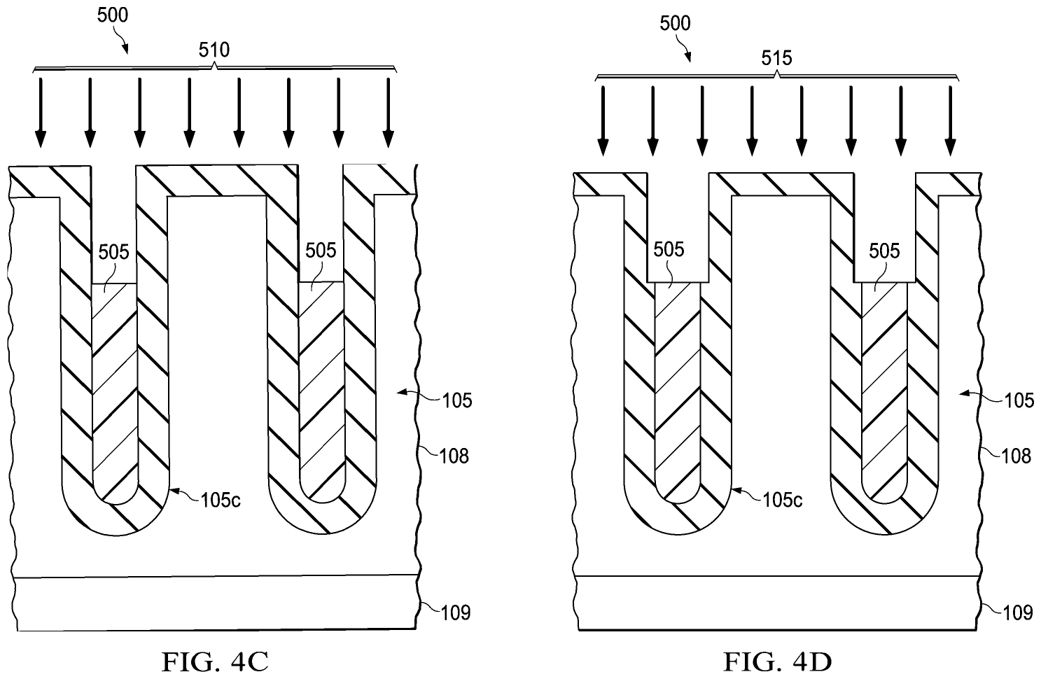

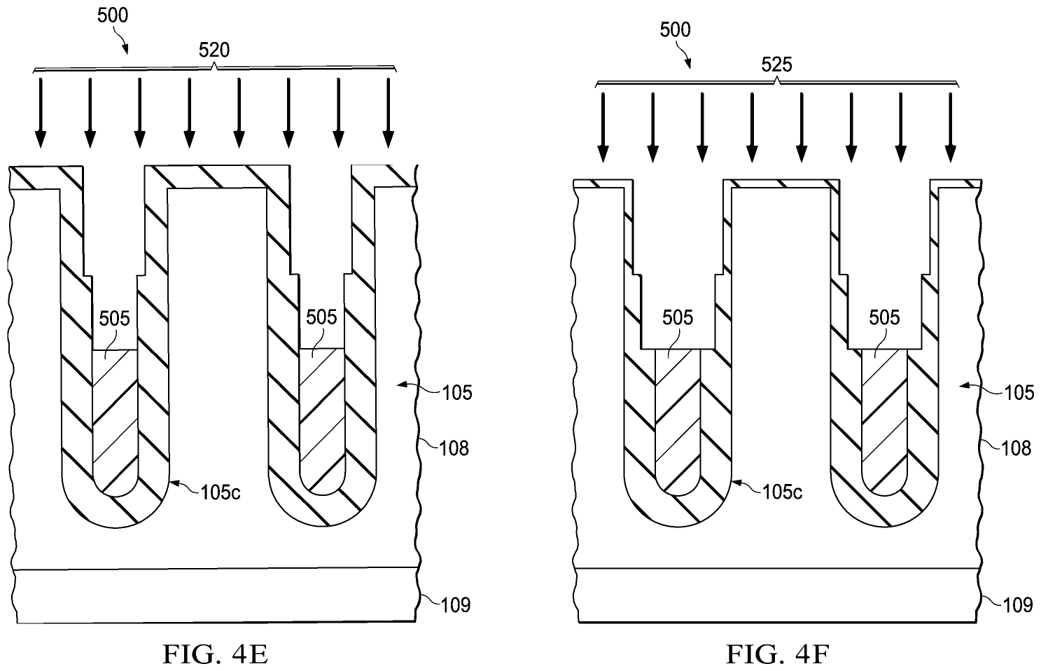

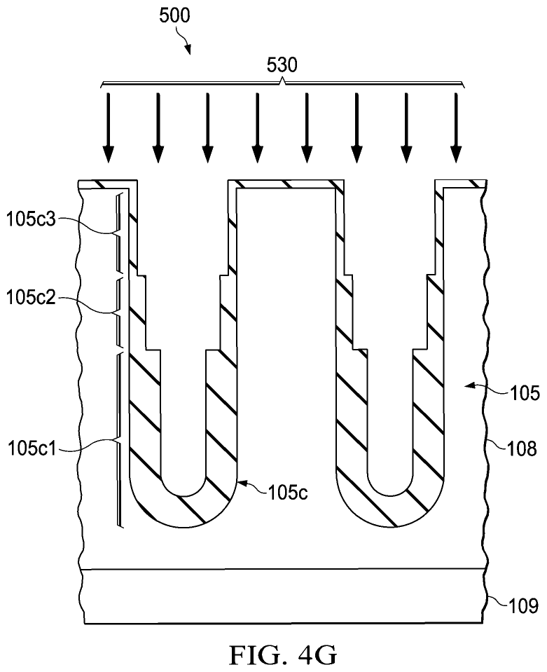

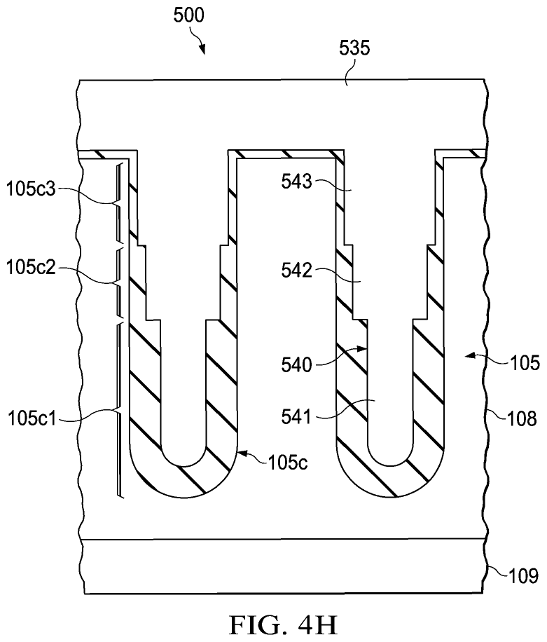

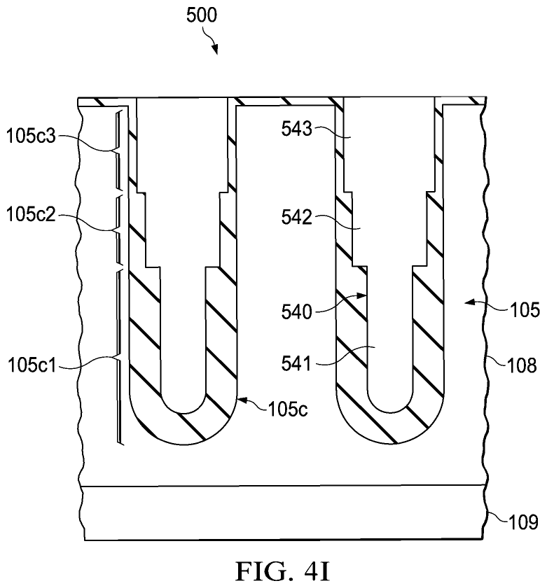

FIGS. 4A-4I illustrate an alternate method 500 of the disclosure for forming a triple width field plate structure that may be used in a trench gate MOSFET device. The method 500 uses a sacrificial layer, such as photoresist, to fill the trench instead of filling the trench with polysilicon as was shown in FIG. 3B. While the following description of the method 500 uses photoresist as one example, those skilled in the pertinent art will appreciate that other sacrificial materials may be used, such as ARC (anti-reflective coating) or other organic spin-coatable material compatible with semiconductor processing.

FIG. 4A illustrates the MOSFET cells 105 after forming the trench wall dielectric layer 105c. The dielectric layer 105c, e.g. a thermal silicon oxide layer, has been formed on exposed surfaces of the surface layer 108.

In FIG. 4B photoresist 505 has been deposited over the substrate 109 and between vertical portions of the dielectric layer 105c. FIG. 4B illustrates the method 500 after an optional etch-back of the photoresist 505 that exposes the dielectric layer 105c.

FIG. 4C illustrates the method 500 during and after removal of a first portion of the photoresist 505, e.g. by an anisotropic plasma etch or ash process 510. The removing exposes a top portion of the dielectric layer 105c at and below a top surface of the surface layer 108.

In FIG. 4D an etch process 515 that is selective to silicon oxide removes a first portion of the dielectric layer 105c that is not protected by the photoresist 505. The etch process 515 may include, e.g. a buffered HF solution sufficiently diluted to provide process control. The etch process 515 thins the dielectric layer 105c over the surface of the surface layer 108 and over the sidewalls of the trenches.

FIG. 4E illustrates the method 500 during and after removal of a second portion of the photoresist 505, e.g. by an anisotropic plasma etch or ash process 520. The removing exposes a middle portion of the dielectric layer 105c below the top portion.

In FIG. 4F an etch process 525 that is selective to silicon oxide removes a second portion of the dielectric layer 105c that is not protected by the photoresist 505. The etch process 525 may again include, e.g. a buffered HF solution. The etch process 525 further thins the dielectric layer 105c over the surface of the surface layer 108 and over the sidewalls of the trenches, resulting in a thinner upper portion and a thicker middle portion of the dielectric layer 105c within the trenches.

FIG. 4G illustrates the method 500 during and after removal of a third portion of the photoresist 505, e.g. by an anisotropic plasma etch or ash process 530. The removing exposes a bottom portion of the dielectric layer 105c below the middle portion. The dielectric layer 105c now has the bottom portion 105c1, middle portion 105c2 and top portion 105c3.

In FIG. 4H a polysilicon layer 535 has been formed within the trenches and over the top surface of the surface layer 108, e.g. by conventional means. Finally, FIG. 41 shows the method 500 after removal of a portion of the polysilicon layer 535 over the top surface of the surface layer 108. The partial removing of the polysilicon layer 535 may include CMP and/or an etch process selective to polysilicon, and separates partially formed triple width field plates 540, each having a bottom portion 541, a middle portion 542 and a top portion 543, respectively corresponding to the bottom portion 105b1, the middle portion 105b2 and the top portion 105b3. Processing of the trench gate MOSFET cells 105 may continue as illustrated by FIG. 3F, et seq. The method 500 may be adapted to provide more than three widths of the partially formed field plates 540, e.g. by using more than two etch process steps to remove portions of the photoresist 505.

The addition of the wider top portion 105b3 is an innovative solution to the undercut issue described previously. Unlike the double-width field plate of some baseline devices, the top portion 105b3 has no significant effect on the electrical operation of transistors employing this feature. Whereas the double-width field plate is typically used to make more uniform the electrical fields in the drift region of the surface layer 108, this advantage is not generally applicable at the top of the field plate 105b, where the electric field is substantially reduced relative to the bottom of the field plate 105b. While providing little to no electrical benefit, the wider top portion 105b3 provides significant processing benefit by reducing the area available for a wet etch, e.g. an HF etch, to attack the dielectric liner 105c3 while removing the dielectric liner 105c from the trench sidewalls in preparation to form a clean gate dielectric layer above the field plate 105b. Moreover, while a thinner dielectric liner dielectric might otherwise result in reduced voltage capacity of the transistor, the described implementations include the realization that such a thinner dielectric liner adjacent the gate 105a can be used to increase the process margin of the transistor while not sacrificing voltage range due to the reduced electric field near the body region 102. Absent this realization, there is no motivation to add the wider top portion 105b3 to the double-width field plate.

### EXAMPLES

Disclosed aspects are further illustrated by the following specific Examples, which should not be construed as limiting the scope or content of this Disclosure in any way.

Probe yield based on the parameter Igss (the gate to source leakage measured at 12 V) of a disclosed trench gate n-channel MOSFET device having a triple width field plate compared to Igss probe yield data of a trench gate n-channel MOSFET device having a double width field plate demonstrated a probe yield about four times higher for the triple width field plate MOSFET device as compared to the double width field plate MOSFET device.

Disclosed aspects can be used to form trench gate MOSFET devices comprising a semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this Disclosure relates will appreciate that many other aspects are possible within the scope of the claimed invention, and further additions, deletions, substitutions and modifications may be made to the described aspects without departing from the scope of this Disclosure.

1. A method of fabricating a transistor, comprising:
forming a plurality of trenches in a semiconductor layer over a semiconductor substrate, the plurality of trenches including a first trench and a second trench;
forming a gate dielectric layer on first and second sidewalls of the trench, and a gate electrode between the first and second sidewalls;
forming a dielectric liner on the first and second sidewalls, the dielectric liner having a first portion at a bottom of the trench with a first thickness, a second portion between the first portion and the gate dielectric layer with a second thickness less than the first thickness, and a third portion between the second portion and the gate dielectric layer with a third thickness less than the second thickness;
forming a conductive field plate in the trench, the field plate having a bottom portion with a first width, a middle portion between the bottom portion and the gate electrode with a second width greater than the first width, and a top portion between the middle portion and the gate electrode with a third width greater than the second width.

2. The method of claim 1, wherein the forming the field plate includes:
forming a dielectric layer on the first and second sidewalls;
filling the trench with an initial filler material comprising polysilicon between the first and second sidewalls;
etching back the initial filler material thereby forming a first remaining polysilicon portion within the trench;
thinning the dielectric layer above the first remaining polysilicon portion;
filling the trench with a second filler material comprising polysilicon;
etching back the second filler material thereby forming a second remaining polysilicon portion within the trench;
thinning the dielectric layer above the second remaining portion; and
filling the trench with a third filler material comprising polysilicon.

3. The method of claim 1, wherein the forming the field plate includes:
forming a dielectric layer on the first and second sidewalls;
filling the trench with a sacrificial layer between the first and second sidewalls;
etching back the sacrificial layer thereby exposing a first portion of the dielectric layer;
thinning the first portion of the dielectric layer;
etching back of the sacrificial layer thereby exposing a second portion of the dielectric layer; and
thinning the first and second portions of the dielectric layer.

4. The method of claim 1, wherein the gate dielectric layer has a thickness in a range from 100 Å to 10,000 Å.

5. The method of claim 1, wherein forming the gate electrode includes forming a recess in the gate electrode.

6. The method of claim 1, wherein the semiconductor substrate is n-type doped.

7. The method of claim 1, further comprising forming a body region between the first and second trenches and a first doped region within the body region, the first doped region providing a source of a trench gate MOSFET and the semiconductor substrate providing a drain of the trench gate MOSFET.

8. The method of claim 7, further comprising depositing a pre-metal dielectric (PMD) layer over the first and second trenches and forming contacts through the PMD layer, including a first contact to the body region and a second contact to the gate electrode, wherein forming the first contact further comprises etching through the first doped region to reach the body region.

9. The method of claim 1, wherein the plurality of trenches are features of a discrete MOSFET device.

10. The method of claim 1, wherein the plurality of trenches are features of a MOSFET device in an integrated circuit.

11. A trench gate metal oxide semiconductor (MOSFET) device, comprising:
a substrate having a semiconductor surface layer doped a first conductivity type;
at least one trench gate MOSFET cell in or over the semiconductor surface layer, including:
a body region in the semiconductor surface layer doped a second conductivity type;
a source region on top of the body region doped the first conductivity type;
a trench extending down from a top side of the semiconductor surface layer, the trench abutting the body region and being lined with a dielectric material;
a field plate comprising polysilicon in the trench; and
a gate electrode over the field plate,
wherein the field plate has a bottom portion with a first width, a middle portion having a second width between the bottom portion and the gate electrode, and a top portion having a third width between the middle portion and the gate electrode, the second width greater than the first width and the third width greater than the second width.

12. The trench gate MOSFET device of claim 11, wherein the trench gate MOSFET device is a discrete device.

13. The trench gate MOSFET device of claim 11, wherein the trench gate MOSFET device is connected within an integrated circuit.

14. The trench gate MOSFET device of claim 11, further comprising a gate dielectric layer between the gate electrode and a trench sidewall, the gate dielectric layer having a thickness in a range from 100 Å to 10,000 Å.

15. The trench gate MOSFET device of claim 11, wherein the gate electrode includes a recess.

16. The trench gate MOSFET device of claim 11, wherein the first conductivity type is n-type.

17. The trench gate MOSFET device of claim 11, wherein the at least one trench gate MOSFET cell is one of a plurality of trench gate MOSFET cells and the gate electrode is one of a corresponding plurality of gate electrodes, and the source region is one of a corresponding plurality of source regions each located between an adjacent pair of field plates, the plurality of source regions providing a combined source region for the plurality of trench gate MOSFET cells and the substrate providing a drain for the plurality of trench gate MOSFET cells.

18. The trench gate MOSFET device of claim 17, further comprising a pre-metal dielectric (PMD) layer over the plurality of trench gate MOSFET cells and contacts through the PMD layer, a first subset of the contacts reaching the body regions under the combined source region, and a second subset reaching the gate electrodes, wherein each of the first subset of contacts electrically connects to a corresponding one of the source regions and a corresponding one of the body regions.

19. The trench gate MOSFET device of claim 11, wherein the field plate comprises doped polysilicon.

20. The trench gate MOSFET device of claim 11, where the field plate comprises undoped polysilicon.
